(19) United States
(12) Patent Application Publication
(10) Pub. No.: US 2022/0377883 A1
(43) Pub. Date: Nov. 24, 2022

(54) PRINTED WIRING BOARD

(71) Applicant: IBIDEN CO., LTD., Ogaki (JP)

(72) Inventors: Shigeto IYODA, Ogaki (JP); Tomoyuki IKEDA, Ogaki (JP)

(73) Assignee: IBIDEN CO., LTD., Ogaki (JP)

(21) Appl. No.: 17/748,183

(22) Filed: May 19, 2022

(30) Foreign Application Priority Data
May 20, 2021 (JP) 2021-085032

(51) Int. Cl. H05K 1/02; H05K 3/46

(52) U.S. Cl. CPC H05K 1/0298; H05K 3/4644; H05K 2201/09209

(57) ABSTRACT

A printed wiring board includes resin insulating layers, and conductor layers including a conductor layer such that the conductor layer includes a conductor circuit and that the conductor circuit has a surface index X/Y in a range of 1.00 to 2.20 where X is a length of an outer circumference of cross section of the conductor circuit, and Y is a length of an outer circumference of a reference quadrangle in the cross section of the conductor circuit. The reference quadrangle has a first reference line drawn with reference to bottom of deepest recess on first side, a second reference line is drawn with reference to bottom of deepest recess on second side, a third reference line is drawn with reference to bottom of deepest recess on third side, and a fourth reference line is drawn with reference to bottom of deepest recess on fourth side of the outer circumference.

### CROSS-REFERENCE TO RELATED APPLICATIONS

The present application is based upon and claims the benefit of priority to Japanese Patent Application No. 2021-085032, filed May 20, 2021, the entire contents of which are incorporated herein by reference.

### BACKGROUND OF THE INVENTION

### Field of the Invention

A technology disclosed herein relates to a printed wiring board.

### Description of Background Art

Japanese Patent Application Laid-Open Publication No. 2012-216685 describes a multilayer substrate including: a stripline that is formed by respectively laminating conductor layers on both sides of a first dielectric layer in which a transmission line is embedded; and second dielectric layers that are respectively laminated on both sides of the stripline. The transmission line and the conductor layers are each formed of a metal foil having a ten-point average roughness (Rz) of 2 μm or less. In Japanese Patent Application Laid-Open Publication No. 2012-216685, the transmission line and the conductor layers are each formed of a metal foil having a ten-point average roughness (Rz) of 2 μm or less, and thereby, a transmission loss when a high-frequency signal is transmitted is reduced. The entire contents of this publication are incorporated herein by reference.

### SUMMARY OF THE INVENTION

According to one aspect of the present invention, a printed wiring board includes resin insulating layers, and conductor layers laminated on the resin insulating layers respectively and including a conductor layer such that the conductor layer includes a conductor circuit and that the conductor circuit has a surface index X/Y in a range of 1.00 to 2.20 where X is a length of an outer circumference of a cross section of the conductor circuit, and Y is a length of an outer circumference of a reference quadrangle in the cross section of the conductor circuit. The reference quadrangle is a virtual quadrangle having a first reference line, a second reference line, a third reference line, and a fourth reference line as four sides such that the first reference line is a virtual line drawn with reference to a bottom of a deepest recess among recesses formed on a first side of the outer circumference, the second reference line is a virtual line drawn with reference to a bottom of a deepest recess among recesses formed on a second side of the outer circumference, the third reference line is a virtual line drawn with reference to a bottom of a deepest recess among recesses formed on a third side of the outer circumference, and the fourth reference line is a virtual line drawn with reference to a bottom of a deepest recess among recesses formed on a fourth side of the outer circumference.

According to another aspect of the present invention, a method for evaluating a printed wiring board includes forming a conductor layer on a resin insulating layer such that the conductor layer is laminated on the resin insulating layer and includes a conductor circuit, and measuring a surface index X/Y of the conductor circuit such that the surface index X/Y is in the range of 1.00 to 2.20 where X is a length of an outer circumference of a cross section of the conductor circuit, and Y is a length of an outer circumference of a reference quadrangle in the cross section of the conductor circuit. The reference quadrangle is a virtual quadrangle having a first reference line, a second reference line, a third reference line, and a fourth reference line as four sides such that the first reference line is a virtual line drawn with reference to a bottom of a deepest recess among recesses formed on a first side of the outer circumference, the second reference line is a virtual line drawn with reference to a bottom of a deepest recess among recesses formed on a second side of the outer circumference, the third reference line is a virtual line drawn with reference to a bottom of a deepest recess among recesses formed on a third side of the outer circumference, and the fourth reference line is a virtual line drawn with reference to a bottom of a deepest recess among recesses formed on a fourth side of the outer circumference.

According to yet another aspect of the present invention, a method for manufacturing a printed wiring board includes forming a conductor layer on a resin insulating layer such that the conductor layer is laminated on the resin insulating layer and includes a conductor circuit and that the conductor circuit has a surface index X/Y in a range of 1.00 to 2.20 where X is a length of an outer circumference of a cross section of the conductor circuit, and Y is a length of an outer circumference of a reference quadrangle in the cross section of the conductor circuit. The reference quadrangle is a virtual quadrangle having a first reference line, a second reference line, a third reference line, and a fourth reference line as four sides such that the first reference line is a virtual line drawn with reference to a bottom of a deepest recess among recesses formed on a first side of the outer circumference, the second reference line is a virtual line drawn with reference to a bottom of a deepest recess among recesses formed on a second side of the outer circumference, the third reference line is a virtual line drawn with reference to a bottom of a deepest recess among recesses formed on a third side of the outer circumference, and the fourth reference line is a virtual line drawn with reference to a bottom of a deepest recess among recesses formed on a fourth side of the outer circumference.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a part of a printed wiring board according to an embodiment of the present invention;

FIG. 2 is a cross-sectional view schematically illustrating a wiring (Example 1) that has been subjected to 1.0 μm etching;

FIG. 3 is a cross-sectional view schematically illustrating a wiring (Example 2) that has been subjected to 0.5 μm etching;

FIG. 4 is a cross-sectional view schematically illustrating a wiring (Example 3) that has not been subjected etching;

FIG. 5 is a graph showing a relationship between a root mean square height (Rq) and a transmission loss of a wiring;

FIG. 6 is a graph showing a relationship between a surface index and a transmission loss of a wiring;

FIG. 7A is a cross-sectional view schematically illustrating a method for manufacturing a printed wiring board according to an embodiment of the present invention;

FIG. 7B is a cross-sectional view schematically illustrating a method for manufacturing a printed wiring board according to an embodiment of the present invention;

FIG. 7C is a cross-sectional view schematically illustrating a method for manufacturing a printed wiring board according to an embodiment of the present invention;

FIG. 7D is a cross-sectional view schematically illustrating a method for manufacturing a printed wiring board according to an embodiment of the present invention;

FIG. 7E is a cross-sectional view schematically illustrating a method for manufacturing a printed wiring board according to an embodiment of the present invention;

FIG. 7F is a cross-sectional view schematically illustrating a method for manufacturing a printed wiring board according to an embodiment of the present invention; and

FIG. 7G is a cross-sectional view schematically illustrating a method for manufacturing a printed wiring board according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### EMBODIMENT

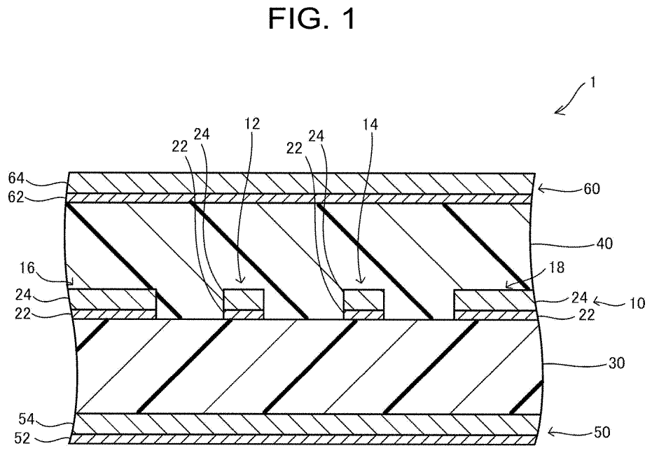

A printed wiring board 1 according to an embodiment of the present invention is formed by alternately laminating multiple resin insulating layers and multiple conductor layers. FIG. 1 is a cross-sectional view illustrating a part of the printed wiring board 1 of the embodiment. As illustrated in FIG. 1, the printed wiring board 1 includes a second conductor layer 50, a first resin insulating layer 30, a first conductor layer 10, a second resin insulating layer 40, and a third conductor layer 60. The second conductor layer 50, the first resin insulating layer 30, the first conductor layer 10, the second resin insulating layer 40, and the third conductor layer 60 are laminated in this order and form a stripline structure. The second conductor layer 50, the first resin insulating layer 30, the first conductor layer 10, the second resin insulating layer 40, and the third conductor layer 60 can form a part of a build-up layer formed on a core substrate. The printed wiring board 1 may have a resin insulating layer and a conductor layer other than the second conductor layer 50, the first resin insulating layer 30, the first conductor layer 10, the second resin insulating layer 40, and the third conductor layer 60.

The second conductor layer 50 is formed of copper. The second conductor layer 50 is formed of a seed layer 52 and an electrolytic plating film 54 on the seed layer 52. The second conductor layer 50 is entirely or partially a solid layer. The second conductor layer 50 is a power line or a ground line.

The first resin insulating layer 30 is formed on the second conductor layer 50. The first resin insulating layer 30 is formed using a thermosetting resin. The first resin insulating layer 30 may contain inorganic particles such as silica particles. The first resin insulating layer 30 may contain a reinforcing material such as a glass cloth. A dielectric loss tangent (Df) of the first resin insulating layer 30 is 0.02 or less.

The first conductor layer 10 is formed on the first resin insulating layer 30. The first conductor layer 10 is formed of copper. The first conductor layer 10 includes wirings (12, 14) and solid layers (16, 18). The wirings (12, 14) are signal lines. The solid layers (16, 18) are each a power line or a ground line. The wirings (12, 14) and the solid layers (16, 18) are each formed of a seed layer 22 and an electrolytic plating film 24 on the seed layer 22. When the above first resin insulating layer 30 contains a reinforcing material such as glass cloth, a copper foil may be provided between the first resin insulating layer 30 and the seed layer 22.

The second resin insulating layer 40 is formed on the first resin insulating layer 30 and the first conductor layer 10. The second resin insulating layer 40 is formed using a thermosetting resin. The second resin insulating layer 40 may contain inorganic particles such as silica particles. The second resin insulating layer 40 may contain a reinforcing material such as a glass cloth. A dielectric loss tangent (Df) of the second resin insulating layer 40 is 0.02 or less.

The third conductor layer 60 is formed on the second resin insulating layer 40. The third conductor layer 60 is formed of copper. The third conductor layer 60 is formed of a seed layer 62 and an electrolytic plating film 64 on the seed layer 62. The third conductor layer 60 is entirely or partially a solid layer. The third conductor layer 60 is a power line or a ground line. When the above second resin insulating layer 40 contains a reinforcing material such as glass cloth, a copper foil may be provided between the second resin insulating layer 40 and the seed layer 62.

As described above, in the embodiment, a stripline structure is formed in which the wirings (12, 14) embedded in the first resin insulating layer 30 and the second resin insulating layer 40 are sandwiched between the second conductor layer 50 and the third conductor layer 60.

Surfaces of Wirings

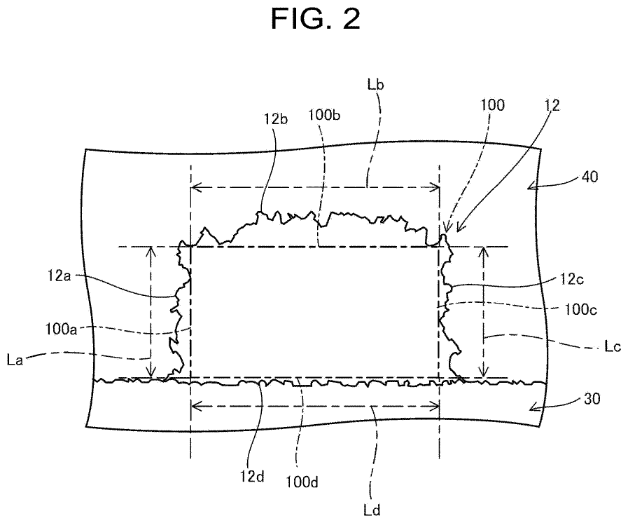

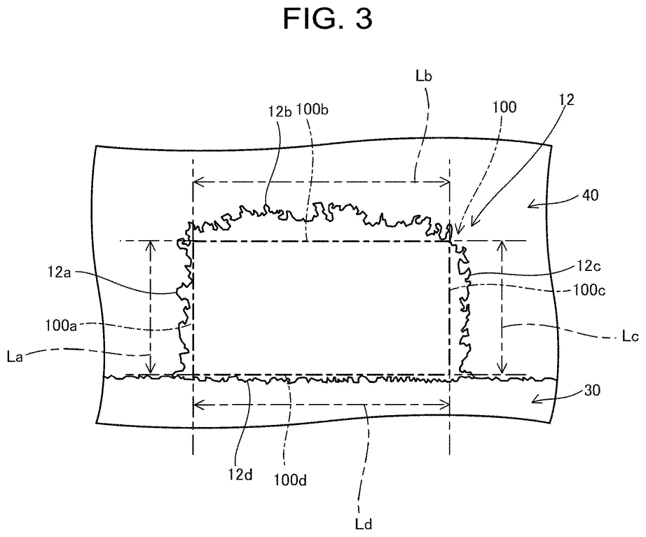

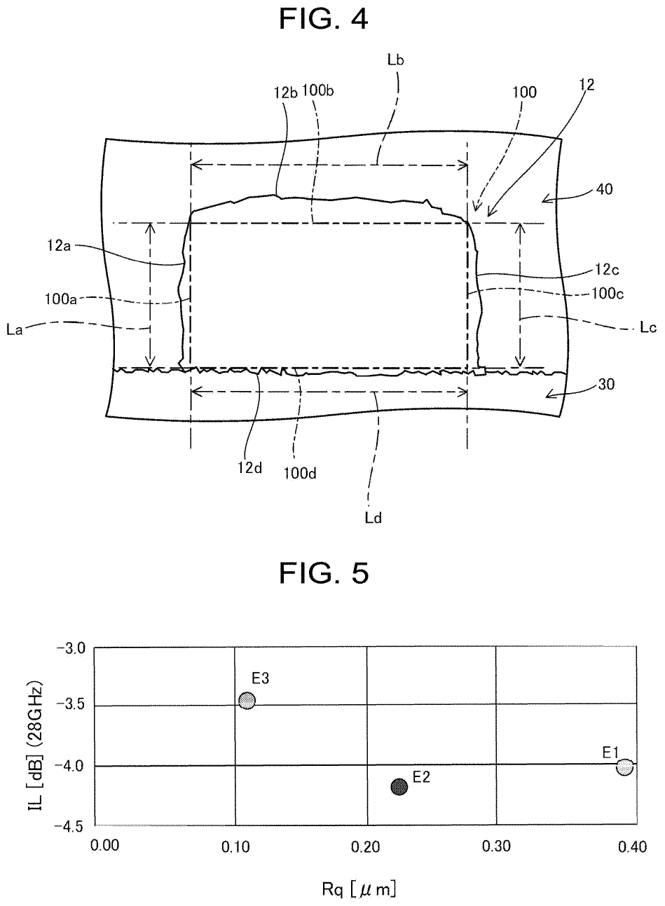

In a formation process of the wirings (12, 14), surfaces of the wirings (12, 14) are roughened by performing etching (for example, a CZ roughening treatment) for rough surface formation. The etching (CZ roughening treatment) for rough surface formation is a treatment performed after a quick etching treatment for seed layer removal. Hereinafter, the etching for rough surface formation may be simply referred to as “etching.” By roughening the surfaces of the wirings (12, 14) by etching, adhesion to the first resin insulating layer 30 is improved. As illustrated in FIGS. 2-4, shapes of the surfaces (rough surfaces) of the wirings (12, 14) differ depending on a condition of the etching (CZ roughening treatment). FIG. 2 illustrates a cross section of the wiring 12 when an etching amount by the etching (CZ roughening treatment) is 1.0 FIG. 3 illustrates a cross section of the wiring 12 when the etching amount by the etching (CZ roughening treatment) is 0.5 FIG. 4 illustrates a cross section of the wiring 12 when the etching (CZ roughening treatment) is not performed after the quick etching treatment. Here, the “etching amount” is a depth amount by which the surface of the wiring is etched in a depth direction by the etching (CZ roughening treatment) for rough surface formation described above. Hereinafter, etching with an etching amount of 0.5 μm may be referred to as “0.5 μm etching.” Etching with an etching amount of 1.0 μm may be referred to as “1.0 μm etching.”

In the embodiment, a root mean square height (Rq) of the surfaces of the wirings (12, 14) is 1.00 μm or less. A ten-point average roughness (Rz) of each of the surfaces of the wirings (12, 14) is 2.00 μm or less. The above numerical values (Rq, Rz) are calculated based on actual measurement values measured using a 3D microscope (for example, a shape analysis laser microscope “VK-X1000”). The surfaces of the wirings (12, 14) each have a surface index of 1.00-2.20. More preferably, the surfaces of the wirings (12, 14) each have a surface index of 1.00-1.80. In the present specification, the “surface index” is a value of X/Y when a length of an outer circumference of the cross section of the wiring 12 is X and a length of an outer circumference of a reference quadrangle 100 (see FIGS. 2-4) of the cross section of the wiring 12 is Y.

The surface index of the surface of the wiring 12 is further described with reference to FIGS. 2-4. In FIGS. 2-4, the wiring 12 is described as an example. However, the same description also applies to the wiring 14. FIG. 2 is a cross-sectional view illustrating an example (Example 1) of the wiring 12 that has been subjected to a 1.0 μm etching treatment. FIG. 3 is a cross-sectional view illustrating an example (Example 2) of the wiring 12 that has been subjected to 0.5 μm etching. FIG. 4 is a cross-sectional view illustrating an example (Example 3) of the wiring 12 that has not been subjected to the etching (CZ roughening treatment) after the quick etching treatment. FIGS. 2-4 are each obtained by cutting the wiring 12 in a plane perpendicular to the first resin insulating layer 30.

The value of X is an actual measurement value of the length of the outer circumference of the cross section of the wiring 12 as illustrated in FIGS. 2-4. The value of X (the actual measurement value of the length of the outer circumference of the cross section of the wiring 12) is obtained by analyzing an image of the cross section of the wiring 12 using image analysis software (for example, image analysis software “Image-Pro Plus 6.2J”). The reference quadrangle 100, which is a reference of the value of Y, is a virtual quadrangle having a first reference line (100a), a second reference line (100b), a third reference line (100c), and a fourth reference line (100d) as four sides.

The first reference line (100a) is a virtual line drawn with reference to a bottom of a deepest recess among multiple recesses formed on a first side (12a) of the outer circumference of the cross section of the wiring 12. The second reference line (100b) is a virtual line drawn with reference to a bottom of a deepest recess among multiple recesses formed on a second side (12b) of the outer circumference of the cross section of the wiring 12. The third reference line (100c) is a virtual line drawn with reference to a bottom of a deepest recess among multiple recesses formed on a third side (12c) of the outer circumference of the cross section of the wiring 12. The fourth reference line (100d) is a virtual line drawn with reference to a bottom of a deepest recess among multiple recesses formed on a fourth side (12d) of the outer circumference of the cross section of the wiring 12. The length (Y) of the outer circumference of the reference quadrangle 100 is a sum of a length (La) of the first reference line (100a), a length (Lb) of the second reference line (100b), a length (Lc) of the third reference line (100c), and a length (Ld) of the fourth reference line (100d).

### Example 1: Wiring Subjected to 1.0 μm Etching

FIG. 2 illustrates an example (Example 1) of the wiring 12 that has been subjected to 1.0 μm etching. Multiple recesses are formed on the outer circumference of the cross section of the wiring 12 of Example 1. The multiple recesses are relatively deep. The root mean square height (Rq) of the surface of the wiring 12 of Example 1 is about 0.40 The ten-point average roughness (Rz) of the surface of the wiring 12 of Example 1 is about 0.80 The surface of the wiring 12 of Example 1 has a surface index of about 1.40. A transmission loss (IL) of the wiring 12 of Example 1 is about −4.00.

### Example 2: Wiring Subjected to 0.5 μm Etching

FIG. 3 illustrates an example (Example 2) of the wiring 12 that has been subjected to 0.5 μm etching. Multiple recesses are formed on the outer circumference of the cross section of the wiring 12 of Example 2. The multiple recesses are shallower than those of Example 1, but the number of the recesses is larger than that of Example 1. The root mean square height (Rq) of the surface of the wiring 12 of Example 2 is about 0.25 The ten-point average roughness (Rz) of the surface of the wiring 12 of Example 2 is about 0.50 The surface of the wiring 12 of Example 2 has a surface index of about 1.80. The root mean square height (Rq) and the ten-point mean roughness (Rz) of the wiring 12 of Example 2 are smaller than those of Example 1, but the value of the surface index (X/Y) is larger than that of Example 1. A transmission loss (IL) of the wiring 12 of Example 2 is about −4.20.

### Example 3: Wiring not Subjected to Etching

FIG. 4 is a cross-sectional view illustrating an example (Example 3) of the wiring 12 that has not been subjected to etching after the quick etching treatment. Substantially no large unevenness is formed on the outer circumference of the cross section of the wiring 12 of Example 3. The root mean square height (Rq) of the surface of the wiring 12 of Example 3 is about 0.10 μm. The ten-point average roughness (Rz) of the surface of the wiring 12 of Example 3 is about 0.20 μm. The surface of the wiring 12 of Example 3 has a surface index of about 1.10. A transmission loss (IL) of the wiring 12 of Example 3 is about −3.50.

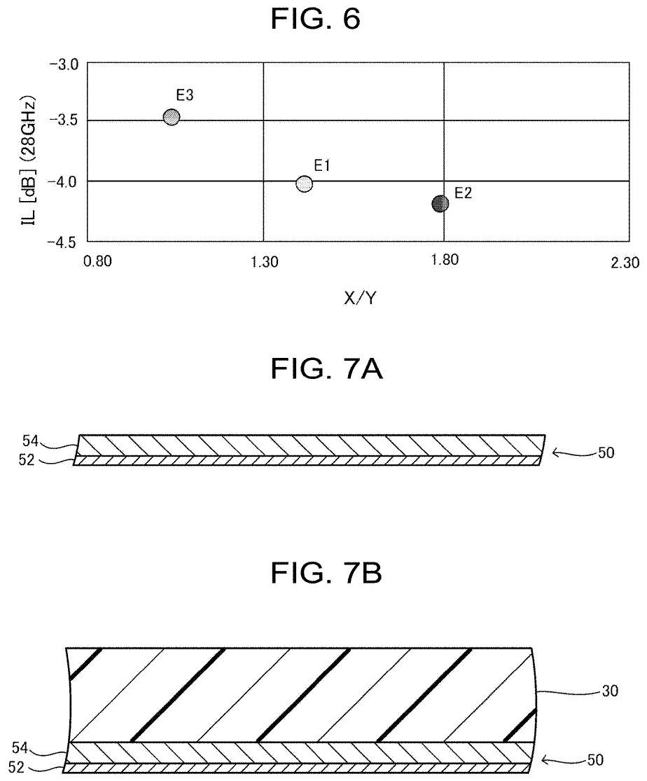

FIG. 5 is a graph showing a relationship between the value of the root mean square height (Rq) and the value of the transmission loss of each of the wirings 12 of Examples 1-3. The horizontal axis represents the root mean square height (Rq). The vertical axis represents the transmission loss. The transmission loss is a measured value at a frequency of 28 GHz. The transmission loss shown in the graph of FIG. 5 is an insertion loss (IL). E1, E2, and E3 in the graph respectively indicate Example 1, Example 2, and Example 3. The graph of FIG. 5 is based on results obtained by actually measuring transmission losses using the wirings 12 of Examples 1-3.

As shown in FIG. 5, the root mean square height (Rq), which is a numerical value representing a surface roughness, decreases in the order of Example 1 (E1), Example 2 (E2), and Example 3 (E3). On the other hand, the transmission loss of Example 2 (E2) is the largest. That is, the root mean square height (Rq), which is a numerical value representing a surface roughness, is not proportional to the actual transmission loss of the wiring 12. It can be seen that even when the root mean square height (Rq) is small, the transmission loss may not be similarly small.

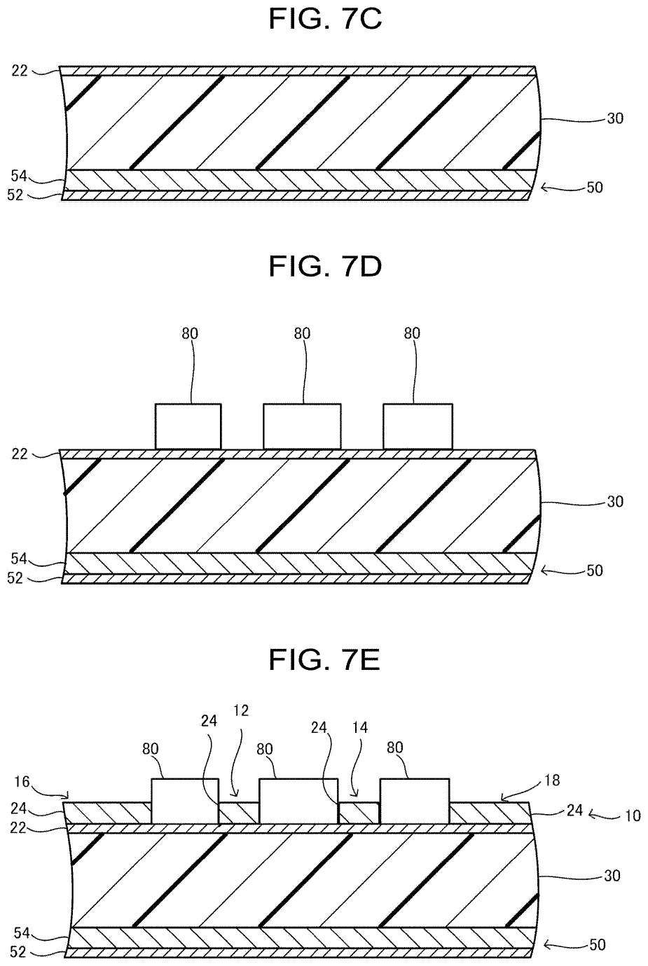

FIG. 6 is a graph showing a relationship between the value of the surface index and the value of the transmission loss of each of the wirings 12 of Examples 1-3. The horizontal axis represents the surface index. The vertical axis represents the transmission loss. E1, E2, and E3 in the graph respectively indicate Example 1, Example 2, and Example 3. The graph in FIG. 6 is based on results obtained by actually measuring transmission losses using the wirings 12 of Examples 1-3.

As shown in FIG. 6, the surface index decreases in the order of Example 2 (E2), Example 1 (E1), and Example 3 (E3). The transmission loss also decreases in the order of Example 2 (E2), Example 1 (E1), and Example 3 (E3). The surface index and the transmission loss of the wiring 12 are proportional to each other. According to the structure of the printed wiring board 1 of the embodiment, a content of a treatment applied to the surface of the wiring 12 can be determined based on the surface index that is proportional to the transmission loss.

When the surface index of each of the wiring (12, 14) is in the range of 1.00-2.20 as in the embodiment, the transmission loss of each of the wirings (12, 14) is relatively small (see FIG. 6). Therefore, according to the embodiment, the printed wiring board 1 having the wirings (12, 14) with low transmission losses is provided. The wirings (12, 14) of the present embodiment are each an example of a “conductor circuit.”

In the printed wiring board 1 of the embodiment, the dielectric loss tangent (Df) of the first resin insulating layer 30 and the dielectric loss tangent (Df) of the second resin insulating layer 40 are 0.02 or less. Therefore, the transmission losses of the wirings (12, 14) are small.

In the printed wiring board 1 of the embodiment, surface indices of an upper surface of the second conductor layer 50, an upper surface of the first resin insulating layer 30, surfaces of the solid layers (16, 18), an upper surface of the second resin insulating layer 40, and an upper surface of the third conductor layer 60 are all larger than 2.20. Since the surface indices of the upper surface of the second conductor layer 50, the upper surface of the first resin insulating layer 30, the surfaces of the solid layers (16, 18), the upper surface of the second resin insulating layer 40, and the upper surface of the third conductor layer 60 are larger than 2.20, a high anchor effect is realized. Further, the second conductor layer 50, the solid layers (16, 18), and the third conductor layer 60 are all each a power line or a ground line, and thus, the transmission loss does not cause a problem.

Method for Manufacturing Printed Wiring Board

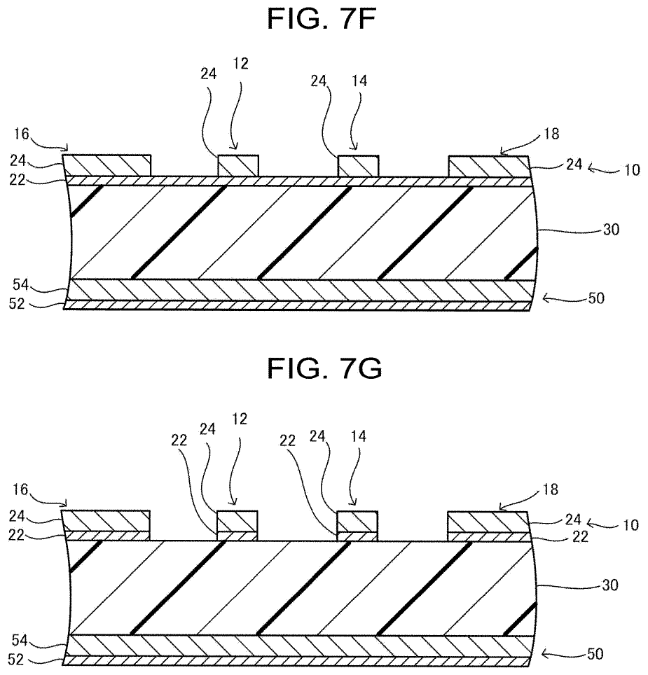

FIGS. 7A-7G illustrate a method for manufacturing the printed wiring board 1 of the embodiment. FIG. 7A illustrates the second conductor layer 50 formed of the seed layer 52 and the electrolytic plating film 54 on the seed layer 52. The upper surface of the second conductor layer 50 is roughened by etching. As illustrated in FIG. 7B, the first resin insulating layer 30 is formed on the second conductor layer 50. The upper surface of the first resin insulating layer 30 is roughened by a permanganate treatment. As illustrated in FIG. 7C, the seed layer 22 is formed on the first resin insulating layer 30. As illustrated in FIG. 7D, a plating resist 80 is formed on the seed layer 22. The plated resist 80 has openings for forming the wirings (12, 14) and the solid layers (16, 18) (FIG. 1).

As illustrated in FIG. 7E, the electrolytic plating film 24 is formed on the seed layer 22 exposed from the plating resist 80. The electrolytic plating film 24 fills the openings. The wirings (12, 14) and the solid layers (16, 18) are formed of the seed layer 22 and the electrolytic plating film 24 formed on the seed layer 22. As a result, the first conductor layer 10 is formed.

As illustrated in FIG. 7F, the plating resist 80 is removed. As illustrated in FIG. 7G, the seed layer 22 exposed from the electrolytic plating film 24 is removed by a quick etching treatment.

After that, in a state in which the wirings (12, 14) are masked, the surfaces of the solid layer (16, 18) are roughened by etching (a CZ roughening treatment). The surfaces of the wirings (12, 14) after the mask is removed are subjected to 1.0 μm etching. It is also possible that the surfaces of the wirings (12, 14) are subjected to 0.5 μm etching. It is also possible that the surfaces of the wirings (12, 14) are not subjected to etching. The surfaces of the wirings (12, 14) may be treated such that the surface indices of the surfaces of the wirings (12, 14) are in the range of 1.00-2.20 (preferably in the range of 1.00-1.80). After that, the second resin insulating layer 40 is formed on the first resin insulating layer 30 and the first conductor layer 10. The upper surface of the first resin insulating layer 30 is roughened by a permanganate treatment. The third conductor layer 60 formed of the seed layer 62 and the electrolytic plating film 64 on the seed layer 62 is formed on the second resin insulating layer 40. The stripline structure is formed. As a result, the printed wiring board 1 (FIG. 1) of the embodiment is obtained.

### First Modified Embodiment

An example of a difference of a printed wiring board 1 of a first modified embodiment from that of the embodiment is described below. In the first modified embodiment, further, the surface indices of the surfaces of the solid layers (16, 18) are 1.00-2.20 (preferably, 1.00-1.80). That is, in the first modified embodiment, the surface indices of the surfaces of the wirings (12, 14) and the solid layers (16, 18) of the first conductor layer 10 are all 1.00-2.20 (preferably 1.00-1.80). In the first modified embodiment, the wirings (12, 14) and the solid layers (16, 18) are each an example of a “conductor circuit.”

### Second Modified Embodiment

In a second modified embodiment, the surface index of at least one of the second conductor layer 50 and the third conductor layer 60 is 1.00-2.20 (preferably 1.00-1.80). That is, in the second modified embodiment, the surface indices of the surfaces of the wirings (12, 14) of the first conductor layer 10 and at least one of the second conductor layer 50 and the third conductor layer 60 are 1.00-2.20 (preferably 1.00-1.80). In the second modified embodiment, the wirings (12, 14) and at least one of the second conductor layer 50 and the third conductor layer 60 are each an example of a “conductor circuit.”

### Third Modified Embodiment

In a third modified embodiment, the surface indices of all the surfaces of the wirings (12, 14) and the solid layers (16, 18) of the first conductor layer 10, the second conductor layer 50, and the third conductor layer 60 are 1.00-2.20 (preferably 1.00-1.80). In the third modified embodiment, the wirings (12, 14), the solid layers (16, 18), the second conductor layer 50, and the third conductor layer 60 are each an example of a “conductor circuit.”

### Fourth Modified Embodiment

In a fourth modified embodiment, a printed wiring board 1 does not have a stripline structure. The printed wiring board 1 of the fourth modified embodiment includes multiple resin insulating layers and multiple conductor layers alternately laminated with the multiple resin insulating layers, and may have any structure as long as a surface of a conductor circuit included in the multiple conductor layers has a surface index of 1.00-2.20.

### Fifth Modified Embodiment

In a fifth modified embodiment, the root mean square height (Rq) of the surfaces of the wirings (12, 14) are larger than 1.0 μm. The ten-point average roughness (Rz) of each of the surfaces of the wirings (12, 14) is larger than 2.00 μm.

### Six Modified Embodiment

In a sixth modified embodiment, the dielectric loss tangent (Df) of each of the first resin insulating layer 30 and the second resin insulating layer 40 is larger than 0.02.

It is thought that it may be possible that a numerical value representing a surface roughness, such as a ten-point average roughness (Rz), an arithmetic mean roughness (Ra), or a root mean square height (Rq), is not proportional to an actual transmission loss of a wiring.

A printed wiring board according to an embodiment of the present invention includes: multiple resin insulating layers; and multiple conductor layers that are alternately laminated with the multiple resin insulating layers. A surface of a conductor circuit included in the multiple conductor layers has a surface index of 1.00-2.20. The surface index is a value of X/Y when, in a cross section of the conductor circuit, a length of an outer circumference of the cross section is X and a length of an outer circumference of a reference quadrangle in the cross section is Y. The reference quadrangle is a virtual quadrangle having a first reference line, a second reference line, a third reference line, and a fourth reference line as four sides. The first reference line is a virtual line drawn with reference to a bottom of a deepest recess among multiple recesses formed on a first side of the outer circumference. The second reference line is a virtual line drawn with reference to a bottom of a deepest recess among multiple recesses formed on a second side of the outer circumference. The third reference line is a virtual line drawn with reference to a bottom of a deepest recess among multiple recesses formed on a third side of the outer circumference. The fourth reference line is a virtual line drawn with reference to a bottom of a deepest recess among multiple recesses formed on a fourth side of the outer circumference.

In a printed wiring board according to an embodiment of the present invention, the conductor circuit has a surface index in the range of 1.00-2.20. It has been found that a surface index and a transmission loss of a conductor circuit are proportional to each other. It has also been found that the transmission loss of the conductor circuit is relatively small when the surface index is in the range of 1.00-2.20. Therefore, according to an embodiment of the present invention, a printed wiring board that includes a conductor circuit having a small transmission loss is provided.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a plurality of resin insulating layers; and
a plurality of conductor layers laminated on the plurality of resin insulating layers respectively and including a conductor layer such that the conductor layer includes a conductor circuit and that the conductor circuit has a surface index X/Y in a range of 1.00 to 2.20 where X is a length of an outer circumference of a cross section of the conductor circuit, and Y is a length of an outer circumference of a reference quadrangle in the cross section of the conductor circuit,
wherein the reference quadrangle is a virtual quadrangle having a first reference line, a second reference line, a third reference line, and a fourth reference line as four sides such that the first reference line is a virtual line drawn with reference to a bottom of a deepest recess among recesses formed on a first side of the outer circumference, the second reference line is a virtual line drawn with reference to a bottom of a deepest recess among recesses formed on a second side of the outer circumference, the third reference line is a virtual line drawn with reference to a bottom of a deepest recess among recesses formed on a third side of the outer circumference, and the fourth reference line is a virtual line drawn with reference to a bottom of a deepest recess among recesses formed on a fourth side of the outer circumference.

2. The printed wiring board according to claim 1, wherein the conductor layer in the plurality of conductor layers includes a signal line and one of a power line and a ground line such that the conductor circuit includes the signal line.

3. The printed wiring board according to claim 2, wherein the conductor circuit further includes one of the power line and the ground line.

4. The printed wiring board according to claim 2, wherein the conductor circuit includes the signal line and does not include the power line and the ground line.

5. The printed wiring board according to claim 1, wherein the conductor layer in the plurality of conductor layers includes a signal line such that the conductor circuit includes the signal line, and the plurality of conductor layers includes a second conductor layer such that the second conductor layer includes one of a power line and a ground line.

6. The printed wiring board according to claim 5, wherein the second conductor layer includes a second conductor circuit such that the second conductor circuit includes one of the power line and the ground line and that a surface of the second conductor circuit has a surface index X/Y in a range of 1.00 to 2.20 where X is a length of an outer circumference of a cross section of the second conductor circuit, and Y is a length of an outer circumference of a reference quadrangle in the cross section of the second conductor circuit, the reference quadrangle is a virtual quadrangle having a first reference line, a second reference line, a third reference line, and a fourth reference line as four sides such that the first reference line is a virtual line drawn with reference to a bottom of a deepest recess among recesses formed on a first side of the outer circumference, the second reference line is a virtual line drawn with reference to a bottom of a deepest recess among recesses formed on a second side of the outer circumference, the third reference line is a virtual line drawn with reference to a bottom of a deepest recess among recesses formed on a third side of the outer circumference, and the fourth reference line is a virtual line drawn with reference to a bottom of a deepest recess among recesses formed on a fourth side of the outer circumference.

7. The printed wiring board according to claim 5, wherein the conductor circuit includes the signal line and does not include the power line and the ground line.

8. The printed wiring board according to claim 5, wherein the plurality of conductor layers includes a third conductor layer having one of a power line and a ground line, the plurality of resin insulating layers includes a first resin insulating layer and a second resin insulating layer such that the second conductor layer, the first resin insulating layer, the first conductor layer, the second resin insulating layer, and the third conductor layer are laminated in an order of the second conductor layer, the first resin insulating layer, the first conductor layer, the second resin insulating layer, and the third conductor layer, and that the second conductor layer, the first resin insulating layer, the first conductor layer, the second resin insulating layer, and the third conductor layer form a stripline structure.

9. The printed wiring board according to claim 1, wherein the conductor circuit of the conductor layer is formed such that a root mean square height Rq of the surface of the conductor circuit is 1.0 μm or less.

10. The printed wiring board according to claim 1, wherein the conductor circuit of the conductor layer is formed such that a ten-point average roughness Rz of the surface of the conductor circuit is 2.0 μm or less.

11. The printed wiring board according to claim 1, wherein the plurality of resin insulating layer is formed such that a dielectric loss tangent of each of the resin insulating layers is 0.02 or less.

12. The printed wiring board according to claim 1, wherein the conductor circuit of the conductor layer is formed such that the surface of the conductor circuit has a surface index of in a range of 1.00 to 1.80.

13. The printed wiring board according to claim 2, wherein the conductor circuit of the conductor layer is formed such that a root mean square height Rq of the surface of the conductor circuit is 1.0 μm or less.

14. The printed wiring board according to claim 2, wherein the conductor circuit of the conductor layer is formed such that a ten-point average roughness Rz of the surface of the conductor circuit is 2.0 μm or less.

15. The printed wiring board according to claim 2, wherein the plurality of resin insulating layer is formed such that a dielectric loss tangent of each of the resin insulating layers is 0.02 or less.

16. The printed wiring board according to claim 2, wherein the conductor circuit of the conductor layer is formed such that the surface of the conductor circuit has a surface index of in a range of 1.00 to 1.80.

17. The printed wiring board according to claim 3, wherein the conductor circuit of the conductor layer is formed such that a root mean square height Rq of the surface of the conductor circuit is 1.0 μm or less.

18. The printed wiring board according to claim 3, wherein the conductor circuit of the conductor layer is formed such that a ten-point average roughness Rz of the surface of the conductor circuit is 2.0 μm or less.

19. A method for evaluating a printed wiring board, comprising:
forming a conductor layer on a resin insulating layer such that the conductor layer is laminated on the resin insulating layer and includes a conductor circuit; and
measuring a surface index X/Y of the conductor circuit such that the surface index X/Y is in a range of 1.00 to 2.20 where X is a length of an outer circumference of a cross section of the conductor circuit, and Y is a length of an outer circumference of a reference quadrangle in the cross section of the conductor circuit,
wherein the reference quadrangle is a virtual quadrangle having a first reference line, a second reference line, a third reference line, and a fourth reference line as four sides such that the first reference line is a virtual line drawn with reference to a bottom of a deepest recess among recesses formed on a first side of the outer circumference, the second reference line is a virtual line drawn with reference to a bottom of a deepest recess among recesses formed on a second side of the outer circumference, the third reference line is a virtual line drawn with reference to a bottom of a deepest recess among recesses formed on a third side of the outer circumference, and the fourth reference line is a virtual line drawn with reference to a bottom of a deepest recess among recesses formed on a fourth side of the outer circumference.

20. A method for manufacturing a printed wiring board, comprising:
forming a conductor layer on a resin insulating layer such that the conductor layer is laminated on the resin insulating layer and includes a conductor circuit and that the conductor circuit has a surface index X/Y in a range of 1.00 to 2.20 where X is a length of an outer circumference of a cross section of the conductor circuit, and Y is a length of an outer circumference of a reference quadrangle in the cross section of the conductor circuit,
wherein the reference quadrangle is a virtual quadrangle having a first reference line, a second reference line, a third reference line, and a fourth reference line as four sides such that the first reference line is a virtual line drawn with reference to a bottom of a deepest recess among recesses formed on a first side of the outer circumference, the second reference line is a virtual line drawn with reference to a bottom of a deepest recess among recesses formed on a second side of the outer circumference, the third reference line is a virtual line drawn with reference to a bottom of a deepest recess among recesses formed on a third side of the outer circumference, and the fourth reference line is a virtual line drawn with reference to a bottom of a deepest recess among recesses formed on a fourth side of the outer circumference.
